(19) United States
(12) Patent Application Publication
(10) Pub. No.: US 2015/0253606 A1
(43) Pub. Date: Sep. 10, 2015

(54) DISPLAY PANEL, MANUFACTURING METHOD THEREOF, AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventor: Wenqing ZHAO, Beijing (CN)

(21) Appl. No.: 14/498,415

(22) Filed: Sep. 26, 2014

(30) Foreign Application Priority Data
Mar. 7, 2014 (CN) 201410083745.9

(51) Int. Cl. G02F 1/1339; G02F 1/1368; H01L 27/12

(52) U.S. Cl. CPC G02F 1/13394; H01L 27/1214; H01L 27/1259; G02F 1/1368; G02F 2001/13398

(57) ABSTRACT

The present invention provides a display panel and the manufacturing method thereof, and a display device comprising the display panel. The display panel comprises an array substrate, an opposite substrate provided opposite to the array substrate, and spacers provided between the array substrate and the opposite substrate, wherein one end of each of the spacers is arranged on one of the array substrate and the opposite substrate, micro-structures, which are used for increasing friction between the spacers and the substrate on which the micro-structures are provided, are provided on the other one of the array substrate and the opposite substrate correspondingly, and the other end of each of the spacers contacts tightly with the micro-structures. The present invention may effectively solve the problem, in the prior art, of shift possibly occurring between the array substrate and the opposite substrate due to the movement of the display panel.

### FIELD OF THE INVENTION

The present invention relates to the field of display technology, and particularly to a display panel, a manufacturing method thereof, and a display device.

### BACKGROUND OF THE INVENTION

A liquid crystal display panel typically comprises an array substrate, a color filter and a liquid crystal layer provided therebetween. Generally, spacers are further disposed between the array substrate and the color filter to maintain the cell thickness of the liquid crystal display panel.

In an existing manufacturing process of a liquid crystal display panel, the array substrate and the color filter need to be cured after having been aligned to form a cell. However, in the process of moving the liquid crystal display panel between a cell-forming equipment and a curing equipment, a shift may occur between the array substrate and the color filter that were well-aligned initially, which affects the alignment accuracy between the array substrate and the color filter of the resulting liquid crystal display panel, and further results in impure color and cross color when displaying pictures on the display panel.

### SUMMARY OF THE INVENTION

In view of the above, an object of the present invention is to provide a display panel and a manufacturing method thereof, as well as a display device, to solve the cross color defect when displaying pictures on the display panel.

An aspect of the present invention provides a display panel, which comprises an array substrate, an opposite substrate provided opposite to the array substrate and spacers provided between the array substrate and the opposite substrate, wherein one end of each of the spacers is arranged on one of the array substrate and the opposite substrate, micro-structures, which are used for increasing friction between the spacers and the substrate on which the micro-structures are provided, are provided on the other one of the array substrate and the opposite substrate correspondingly, and the other end of each of the spacers contacts tightly with the micro-structures.

Preferably, the spacers are provided on non-display areas of the one of the array substrate and the opposite substrate, and the micro-structures are provided on non-display areas of the other one of the array substrate and the opposite substrate.

Preferably, the spacers are columnar and made of an elastic material, and are provided on the one of the array substrate and the opposite substrate at intervals,

Preferably, each of the micro-structures corresponds to one or more of the spacers, and the ends of the spacers contacting tightly with the micro-structures are embedded in the micro-structures which are provided corresponding to the spacers.

Preferably, each of the micro-structures comprises at least one groove or protrusion, and the at least one groove or protrusion is distributed in a preset pattern.

Preferably, depths of the grooves of the micro-structures are 2%˜10% of heights of the spacers, or heights of the protrusions of the micro-structures are 2%˜10% of those of the spacers.

Preferably, one end of each of the spacers is arranged on the opposite substrate, and the micro-structures are formed of one or more layers of a passivation layer, a source-drain electrode layer, an active layer, a gate insulation layer and a gate metal layer of the array substrate.

Alternatively, one end of each of the spacers is arranged on the array substrate, and the micro-structures are formed of one or more layers of a color filter layer, a black matrix and an overcoat layer of the opposite substrate.

Alternatively, the micro-structures are formed on a passivation layer of the array substrate or an overcoat layer of the opposite substrate through a patterning process.

Another aspect of the present invention provides a manufacturing method of a display panel, which comprises steps of:
manufacturing an array substrate and an opposite substrate, and providing spacers on one of the array substrate and the opposite substrate; and
providing micro-structures on the other one of the array substrate and the opposite substrate correspondingly, such that the spacers contact tightly with the micro-structures after the array substrate and the opposite substrate are aligned to form a cell,
wherein the micro-structures are used for increasing friction between the spacers and the substrate on which the micro-structures are provided.

Preferably, the step of providing spacers on one of the array substrate and the opposite substrate comprises:
forming a pattern including the spacers on a passivation layer of the array substrate through a patterning process; and
the step of providing micro-structures on the other one of the array substrate and the opposite substrate correspondingly comprises:
forming a pattern including the micro-structures on a color filter layer or an overcoat layer of the opposite substrate through a patterning process.

Preferably, the step of providing spacers on one of the array substrate and the opposite substrate comprises:
forming a pattern including the spacers on an overcoat layer of the opposite substrate through a patterning process; and
the step of providing micro-structures on the other one of the array substrate and the opposite substrate correspondingly comprises:
forming a pattern including the micro-structures on one or more layers of a passivation layer, a source-drain electrode layer, an active layer, a gate insulation layer and a gate metal layer of the array substrate through a patterning process.

Preferably, the step of providing micro-structures on the other one of the array substrate and the opposite substrate correspondingly comprises:
forming the pattern including the micro-structures while manufacturing the source-drain electrode layer and/or the active layer of the array substrate through a patterning process.

Preferably, the step of providing micro-structures on the other one of the array substrate and the opposite substrate correspondingly comprises:
forming the pattern including the micro-structures on the passivation layer of the array substrate through a patterning process.

Still another aspect of the present invention provides a display device, which comprises the above display panel provided by the present invention.

It can be seen that, with the micro-structures provided on the substrate opposite to the substrate on which spacers are provided, the spacers can contact tightly with the micro-structures after the array substrate and the opposite substrate are aligned to form a cell, which increases friction between the spacers and the contact surface where the spacers contact with the substrate opposite thereto, thus effectively solving the problem, in the prior art, of shift possibly occurring between the array substrate and the opposite substrate due to the movement of the display panel.

### BRIEF DESCRIPTION OF THE DRAWINGS

The accompanying drawings, as a part of the description, are used for providing a further understanding of the present invention, and explaining the present invention together with the following specific implementations, rather than limiting the present invention. In the drawings:

FIG. 1 is a schematic diagram of an example of a display panel provided by the present invention;

FIG. 2 is a schematic diagram of another example of a display panel provided by the present invention;

FIG. 3 is a schematic diagram illustrating an example of distribution of multiple grooves of a micro-structure provided by the present invention;

FIG. 4 is a schematic diagram illustrating another example of distribution of multiple grooves of a micro-structure provided by the present invention;

FIG. 5 is a schematic diagram of still another example of a display panel provided by the present invention; and

FIG. 6 is a flow chart of a manufacturing method of a display panel provided by the present invention.

### DETAILED DESCRIPTION OF THE EMBODIMENTS

The specific implementations of the present invention will be described in detail below in conjunction with the accompanying drawings. It should be understood that the specific implementations described herein are merely used for describing and explaining the present invention, rather than limiting the present invention.

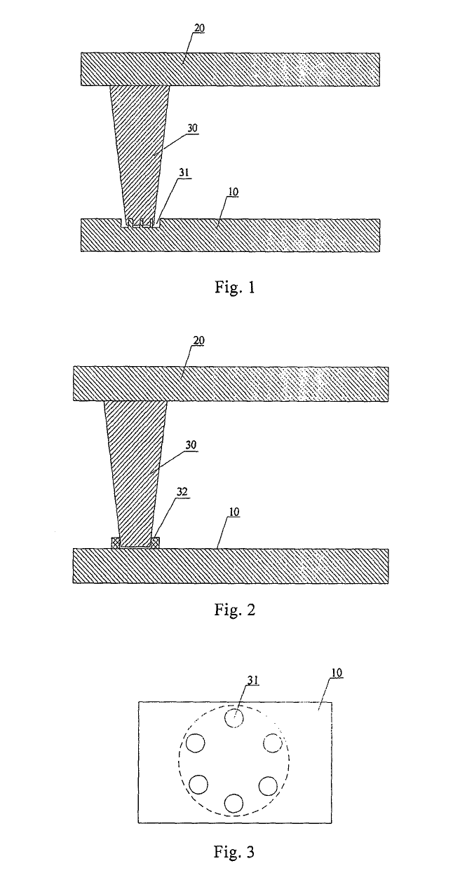

An aspect of the present invention provides a display panel, which, as shown in FIG. 1, may comprise an array substrate 10 and an opposite substrate 20 provided opposite to the array substrate 10, and spacers 30 may be provided between the array substrate 10 and the opposite substrate 20. One end of each of the spacers 30 may be arranged on one of the array substrate 10 and the opposite substrate 20, micro-structures may be provided on the other one of the array substrate 10 and the opposite substrate 20, and the other end of each of the spacers 30 contacts tightly with the micro-structure.

It should be understood that, as the array substrate 10 and the opposite substrate 20 are provided opposite to each other, and the spacers 30 are provided between the array substrate 10 and the opposite substrate 20. Specifically, the spacers 30 may be provided on a surface of the array substrate 10 facing the opposite substrate 20, and contact tightly with the micro-structures provided on a surface of the opposite substrate 20 facing the array substrate 10; or the spacers 30 may be provided on a surface of the opposite substrate 20 facing the array substrate 10, and contact tightly with the micro-structures provided on a surface of the array substrate 10 facing the opposite substrate 20. Here, the array substrate 10 may be a substrate provided with thin film transistors and pixel structures, the opposite substrate 20 may be a substrate provided with color resin for filtering light, and of course, the array substrate 10 and the opposite substrate 20 may be substrates with other structures.

In an existing manufacturing process of a display panel, during the moving of the array substrate and the opposite substrate that have been aligned to form a cell, a shift may occur between the array substrate and the opposite substrate, which may lead to shift in alignment, and further result in cross color when displaying pictures on the display panel.

In the above display panel provided by the present invention, the micro-structures are provided on the array substrate 10 or on the opposite substrate 20, the micro-structure can contact tightly with one end of each of the spacers 30 to increase friction between the substrate on which the micro-structures are provided and the spacers 30, and thus the relative position between the array substrate 10 and the opposite substrate 20 can be fixed. The micro-structures may be provided on a side opposite to the spacers 30, and specifically, when the spacers 30 are provided on the opposite substrate 20, the micro-structures may be provided on the array substrate 10; when the spacers 30 are provided on the array substrate 10, the micro-structures may be provided on the opposite substrate 20.

Specifically, the micro-structures may be formed to be uneven patterns. When the array substrate 10 and the opposite substrate 20 are aligned to form a cell, the spacers 30 contact with the uneven patterns formed as the micro-structures. In this case, the friction between the spacers 30 and the substrate opposite to the spacers 30 (i.e. the substrate on which the micro-structures are provided) can be effectively increased, thus preventing shift from occurring between the array substrate 10 and the opposite substrate 20 in the process of moving the display panel.

Further, the spacers 30 may be provided on non-display areas of one of the array substrate 10 and the opposite substrate 20, and the micro-structures may be provided on non-display areas of the other one of the array substrate 10 and the opposite substrate 20. Providing the spacers 30 and the micro-structures on the non-display areas may avoid impact on display performance of the display panel.

It may be understood that the spacers 30 and the micro-structures may also be provided on display areas without affecting the display performance of the display panel.

Further, the spacers 30 may be columnar and may be made of an elastic material, and may be provided on one of the array substrate 10 and the opposite substrate 20 at intervals. The columnar spacers 30 can maintain the cell thickness of the display panel stably, and can be formed easily. Preferably, the spacers 30 may be formed through a patterning process using a resin material.

Further, each of the micro-structures may correspond to one or more of the spacers 30, and one end of the spacer 30 contacting tightly with the micro-structure is embedded in the micro-structure corresponding to the spacer 30. Specifically, every micro-structure may correspond to one or more spacers 30, since the spacers 30 are elastic, one end of the spacer 30 contacting with the micro-structure can be embedded in the micro-structure corresponding to this spacer 30 after the array substrate 10 and the opposite substrate 20 are aligned to form a cell, and thus the friction between the spacer 30 and the micro-structure can be further increased, so as to fix the relative position between the array substrate 10 and the opposite substrate 20 more securely.

Further, the micro-structures may comprise a plurality of grooves or protrusions, and the grooves or protrusions may be distributed in a preset pattern.

Specifically, as shown in FIG. 1, each micro-structure may include a plurality of grooves 31, and the plurality of grooves 31 may be distributed in a present pattern within the corresponding area where the spacer 30 contact with the substrate opposite thereto, such that the spacer 30 can be embedded in the plurality of grooves 31 corresponding to the spacer 30 after the array substrate 10 and the opposite substrate 20 are aligned to form a cell; alternatively, as shown in FIG. 2, each micro-structure may include a plurality of protrusions 32, and the plurality of protrusions 32 may be distributed in a present pattern within the corresponding area where the spacer 30 contacts with the substrate opposite thereto, such that the spacer 30 can be embedded in the pattern formed with the plurality of protrusions 32 corresponding to the spacer 30 after the array substrate 10 and the opposite substrate 20 are aligned to form a cell. Of course, the micro-structure in FIG. 2 may include one protrusion 32 (e.g. a ring-like protrusion 32), at this point, one micro-structure corresponds to one spacer 30, and one end of the spacer 30 can be embedded in the pattern formed by the protrusion 32 after the array substrate 10 and the opposite substrate 20 are aligned to form a cell.

In the above structure, the micro-structure may include one or more sets of grooves 31, or one or more sets of protrusions 32, such that one micro-structure may correspond to one or more spacers 30. Here, one set of grooves 31 or one set of protrusions 32 refer to the grooves 31 or protrusions 32 distributed in the preset pattern within the corresponding area where one spacer 30 contacts with the substrate opposite to the spacer 30. After the array substrate 10 and the opposite substrate 20 are aligned to form a cell, each spacer 30 can be embedded in the plurality of grooves 31 corresponding to the spacer 30, or embedded in the pattern formed by the plurality of protrusions 32 corresponding to the spacer 30, and thus the friction between the spacer 30 and the substrate opposite to the spacer 30 can be increased.

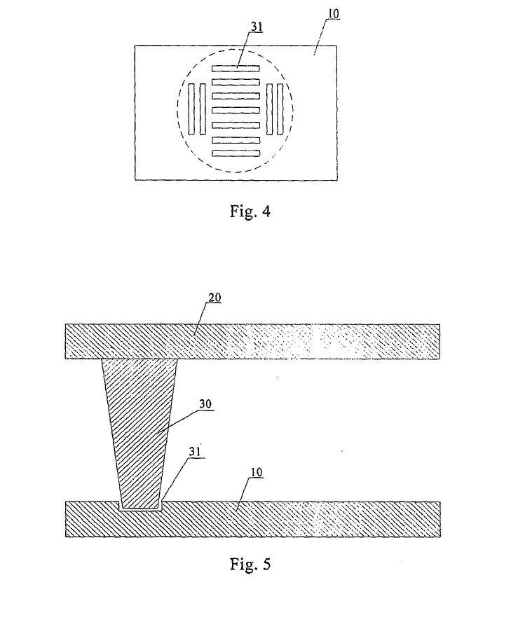

The distribution of the plurality of grooves 31 or protrusions 32 may be set as required, and is not limited in the present invention. Taking the grooves 31 as an example, as shown in FIG. 3, the plurality of grooves 31 may be distributed to be ring-like; alternatively, as shown in FIG. 4, the plurality of grooves 31 may be elongated, and be distributed in the same manner as shown in FIG. 4. In the examples shown in FIGS. 3 and 4, the area surrounded by the dotted line is the contacting area between the spacer 30 and the array substrate 10, and one end of the spacer 30 can be partially embedded in the plurality of grooves 31 in the area after the array substrate 10 and the opposite substrate 20 are aligned to form a cell.

In addition, when the micro-structures include grooves 31, one groove 31 may correspond to one spacer 30, as shown in FIG. 5, and one end of the spacer 30 can be located in this groove 31 after the array substrate 10 and the opposite substrate 20 are aligned to form a cell.

Further, the depth of the groove 31 of the micro-structure may be 2%˜10% of the height of the spacer 30, or the height of the protrusion 32 of the micro-structure is 2%˜10% of that of the spacer. Generally, the spacer 30 is made of resin with elasticity, the spacer 30 may be compressed to a certain extent after the array substrate 10 and the opposite substrate 20 are aligned to form a cell, and generally the compression ratio is about 15%˜30% of the height of the spacer 30. Therefore, the depth of the groove of the micro-structure is set to be 2%˜10% of the height of the spacer, or the height of the protrusion of the micro-structure is set to be 2%˜10% of that of the spacer, so that the spacer 30 can embedded in the micro-structure stably and the cell thickness of the display panel can be ensured after the array substrate 10 and the opposite substrate 20 are aligned to form a cell.

Specifically, one end of each of the spacers 30 may be arranged on the opposite substrate 20, and the micro-structures may include grooves 31, which may be formed of one or more layers of a passivation layer, a source-drain electrode layer, an active layer, a gate insulation layer and a gate metal layer of the array substrate 10. Specifically, in forming a pattern of the source-drain electrode layer, the active layer, the gate insulation layer or the gate metal layer of the array substrate 10, a pattern including the grooves may be formed on one or more of these layers at the same time, such that a pattern including the grooves may be formed on the passivation layer accordingly after the passivation layer is deposited on the source-drain electrode layer. Alternatively, a pattern including the grooves may be directly formed on the passivation layer through a patterning process. It can be understood that, the above merely describes preferable implementations provided by the present invention, and in addition to the above implementations, a pattern layer including the grooves may be separately provided on the passivation layer.

Alternatively, one end of each of the spacers 30 may be provided on the array substrate 10, and the micro-structures may include grooves 31, which may be formed of one or more layers of a color filter layer, a black matrix and an overcoat layer of the opposite substrate 20. Specifically, in forming a pattern of the color filter layer, the black matrix or the overcoat layer of the opposite substrate 20, a pattern including the grooves may be formed on one or more of these layers at the same time, such that a pattern including the micro-structures may be formed on the overcoat layer of the opposite substrate 20. Alternatively, a pattern including the micro-structures may be directly formed on the overcoat layer through a patterning process. It can be understood that, the above merely describes preferable implementations provided by the present invention, and in addition to the above implementations, a pattern layer including the grooves may be separately provided on the overcoat layer.

It should be noted that, although description has been given above by taking the micro-structures including the grooves as an example, in fact, under the condition of multiple grooves or protrusions, the sides of the grooves may be considered as protrusions and portions between adjacent protrusions may form grooves as shown in FIG. 1, since the grooves and the protrusions are counterparts. Therefore, the above description also applies to a structure in which the micro-structures include the protrusions.

It can be understood that the structures of the source-drain electrode layer, the active layer, the gate insulation layer, the gate metal layer and the passivation layer on the array substrate 10 and the structures of the color filter layer, the black matrix and the overcoat layer on the opposite substrate 20 in the embodiments of the present invention may be known structures existing in the prior art, and therefore are not described in detail here. In addition, the array substrate 10 and the opposite substrate 20 may also include other layers, such as an electrode layer, a dielectric layer, and the like, and the pattern of the micro-structures may also be formed of these layers.

It should be noted that in the above display panel provided by the present invention, after a cell is formed, all of the spacers 30 may contact tightly with the micro-structures, or only a part of the spacers 30 may contact tightly with the micro-structures.

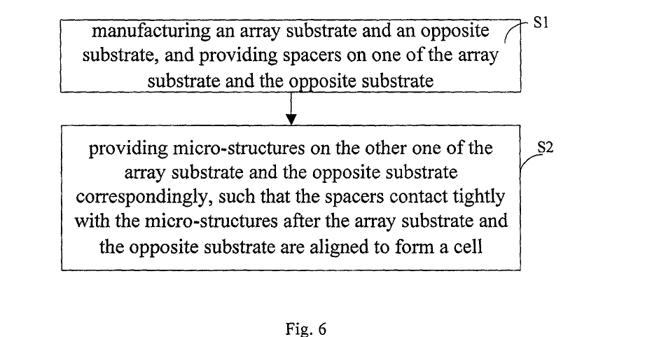

As another aspect of the present invention, a manufacturing method of a display panel is provided for manufacturing the display panel provided by the present invention. As shown in FIG. 6, the manufacturing method of a display panel comprises steps of:

S1: manufacturing an array substrate and an opposite substrate, and providing spacers on one of the array substrate and the opposite substrate; and

S2: providing micro-structures on the other one of the array substrate and the opposite substrate correspondingly, such that the spacers contact tightly with the micro-structures when the array substrate and the opposite substrate are aligned to form a cell.

Further, providing spacers on one of the array substrate and the opposite substrate in step S1 may comprises:
forming a pattern including the spacers on a passivation layer of the array substrate through a patterning process.

In step S2, providing micro-structures on the other one of the array substrate and the opposite substrate correspondingly may comprise:
forming a pattern including the micro-structures on a color filter layer or an overcoat layer of the opposite substrate through a patterning process.

In general, an array substrate is sequentially provided with a gate metal layer, a gate insulation layer, an active layer, a source-drain electrode layer and a passivation layer from bottom to top. A resin layer for manufacturing spacers and a photoresist layer may be deposited on the passivation layer of the array substrate, and then the pattern including the spacers are formed on the passivation layer through the processes including exposure, development, etching and the like. Of course, the array substrate may include other structures such as an electrode layer, a dielectric layer, and the like.

An opposite substrate generally includes a color filter layer and an overcoat layer provided on and covering the color filter layer. In forming the micro-structures on the opposite substrate, the color filter layer on the opposite substrate may be exposed directly to form a pattern including the micro-structures, such that when the overcoat layer is deposited on the color filter layer, a pattern including the micro-structures is accordingly formed on the overcoat layer; alternatively, the overcoat layer on the opposite substrate may be exposed directly to form a pattern including the micro-structures on the overcoat layer. Here, the color filter layer generally includes a red resin layer, a green resin layer, a blue resin layer or a resin layer of other colors, as well as the black matrix for separating respective color pixel units, and the micro-structures may be formed of one or more layers of these layers.

It can be understood that, the above patterning process may also include forming a pattern including the micro-structures and a pattern including the spacers by means of printing or the like.

Alternatively, providing spacers on one of the array substrate and the opposite substrate in step S1 may comprises:
forming a pattern including the micro-structures on one or more layers of the passivation layer, the source-drain electrode layer, the active layer, the gate insulation layer and the gate metal layer of the array substrate through a patterning process, while manufacturing the passivation layer, the source-drain electrode layer, the active layer, the gate insulation layer or the gate metal layer of the array substrate.

Alternatively, the processes such as depositing, exposure, development, etching and the like may be used to form the spacers on the color filter layer or the overcoat layer of the opposite substrate.

While manufacturing the source-drain electrode layer, the active layer, the gate insulation layer or the gate metal layer of the array substrate, a pattern including the micro-structures may be formed on one or more layers of the foregoing layers through a patterning process, such that when the passivation layer is deposited on the source-drain electrode layer, a pattern including the above micro-structures is accordingly formed on the passivation layer. Alternatively, a pattern including the micro-structures is directly formed on the passivation layer using a patterning process.

Preferably, a pattern including the above micro-structures may be formed on the source-drain electrode layer while manufacturing the source-drain electrode layer.

Alternatively, a pattern including the above micro-structures may be formed on the active layer while manufacturing the active layer.

From the above description of the display panel and the manufacturing method thereof provided by the present invention, it can be seen that, with the micro-structures provided on the substrate opposite to the spacers, the spacers can contact tightly with the micro-structures to increase the friction therebetween after the array substrate and the opposite substrate are aligned to form a cell, thus stably fixing the relative position between the array substrate and the opposite substrate.

In the present invention, one end of each of the spacers may be embedded in the micro-structures including a plurality of grooves or protrusions, which may effectively solve the problem, in the prior art, of shift possibly occurring between the array substrate and the opposite substrate due to the movement of the display panel, and thus the alignment accuracy can be ensured between the array substrate and the opposite substrate, and cross color can be avoided when displaying pictures on the display panel.

As still another aspect of the present invention, a display device is provided, and the display device includes the above display panel provided by the present invention.

It can be understood that, above implementations are merely exemplary implementations used for explaining the principle of the present invention, but the present invention is not limited thereto. For those skilled in the art, various modifications and improvements may be made without departing from the spirit and essence of the present invention, and these modifications and improvements are deemed as the protection scope of the present invention.

1. A display panel, comprising an array substrate, an opposite substrate provided opposite to the array substrate, and spacers provided between the array substrate and the opposite substrate, wherein one end of each of the spacers is arranged on one of the array substrate and the opposite substrate, micro-structures, which are used for increasing friction between the spacers and the substrate on which the micro-structures are provided, are provided on the other one of the array substrate and the opposite substrate correspondingly, and the other end of each of the spacers contacts tightly with the micro-structures.

2. The display panel of claim 1, wherein the spacers are provided on non-display areas of the one of the array substrate and the opposite substrate, and the micro-structures are provided on non-display areas of the other one of the array substrate and the opposite substrate correspondingly.

3. The display panel of claim 1, wherein the spacers are columnar and made of an elastic material, and are provided on the one of the array substrate and the opposite substrate at intervals.

4. The display panel of claim 1, wherein each of the micro-structures corresponds to one or more of the spacers, and the ends of the spacers contacting tightly with the micro-structures are embedded in the micro-structures which are provided corresponding to the spacers.

5. The display panel of claim 1, wherein each of the micro-structures comprises at least one groove or protrusion, and the at least one groove or protrusion is distributed in a preset pattern.

6. The display panel of claim 5, wherein, depths of the grooves of the micro-structures are 2%˜10% of heights of the spacers, or heights of the protrusions of the micro-structures are 2%˜10% of those of the spacers.

7. The display panel of claim 6, wherein one end of each of the spacers is arranged on the opposite substrate, and the micro-structures are formed of one or more layers of a passivation layer, a source-drain electrode layer, an active layer, a gate insulation layer and a gate metal layer of the array substrate.

8. The display panel of claim 6, wherein one end of each of the spacers is arranged on the array substrate, and the micro-structures are formed of one or more layers of a color filter layer, a black matrix and an overcoat layer of the opposite substrate.

9. The display panel of claim 6, wherein the micro-structures are formed on a passivation layer of the array substrate or an overcoat layer of the opposite substrate through a patterning process.

10. A manufacturing method of a display panel, comprising steps of:
manufacturing an array substrate and an opposite substrate, and providing spacers on one of the array substrate and the opposite substrate; and
providing micro-structures on the other one of the array substrate and the opposite substrate correspondingly, such that the spacers contact tightly with the micro-structures after the array substrate and the opposite substrate are aligned to form a cell,
wherein the micro-structures are used for increasing friction between the spacers and the substrate on which the micro-structures are provided.

11. The manufacturing method of a display panel of claim 10, wherein, the step of providing spacers on one of the array substrate and the opposite substrate comprises:
forming a pattern including the spacers on a passivation layer of the array substrate through a patterning process; and
the step of providing micro-structures on the other one of the array substrate and the opposite substrate correspondingly comprises:
forming a pattern including the micro-structures on a color filter layer or an overcoat layer of the opposite substrate through a patterning process.

12. The manufacturing method of a display panel of claim 10, wherein, the step of providing spacers on one of the array substrate and the opposite substrate comprises:
forming a pattern including the spacers on an overcoat layer of the opposite substrate through a patterning process; and
the step of providing micro-structures on the other one of the array substrate and the opposite substrate correspondingly comprises:
forming a pattern including the micro-structures on one or more layers of a passivation layer, a source-drain electrode layer, an active layer, a gate insulation layer and a gate metal layer of the array substrate through a patterning process.

13. The manufacturing method of a display panel of claim 12, wherein, the step of providing micro-structures on the other one of the array substrate and the opposite substrate correspondingly comprises:
forming the pattern including the micro-structures while manufacturing the source-drain electrode layer and/or the active layer of the array substrate through a patterning process.

14. The manufacturing method of a display panel of claim 12, wherein, the step of providing micro-structures on the other one of the array substrate and the opposite substrate correspondingly comprises:
forming the pattern including the micro-structures on the passivation layer of the array substrate through a patterning process.

15. A display device, comprising a display panel, which comprises an array substrate, an opposite substrate provided opposite to the array substrate, and spacers provided between the array substrate and the opposite substrate, wherein one end of each of the spacers is arranged on one of the array substrate and the opposite substrate, micro-structures, which are used for increasing friction between the spacers and the substrate on which the micro-structures are provided, are provided on the other one of the array substrate and the opposite substrate correspondingly, and the other end of each of the spacers contacts tightly with the micro-structures.

16. The display device of claim 15, wherein the spacers are provided on non-display areas of the one of the array substrate and the opposite substrate, and the micro-structures are provided on non-display areas of the other one of the array substrate and the opposite substrate correspondingly.

17. The display device of claim 15, wherein the spacers are columnar and made of an elastic material, and are provided on the one of the array substrate and the opposite substrate at intervals.

18. The display device of claim 15, wherein each of the micro-structures corresponds to one or more of the spacers, and the ends of the spacers contacting tightly with the micro-structures are embedded in the micro-structures which are provided corresponding to the spacers.

19. The display device of claim 15, wherein each of the micro-structures comprises at least one groove or protrusion, and the at least one groove or protrusion is distributed in a preset pattern.

20. The display device of claim 19, wherein depths of the grooves of the micro-structures are 2%˜10% of heights of the spacers, or heights of the protrusions of the micro-structures are 2%˜10% of those of the spacers.
